(19) United States
(12) Patent Application Publication
(10) Pub. No.: US 2007/0210323 A1
(43) Pub. Date: Sep. 13, 2007

(54) Optical Device

(75) Inventors: Jonathan J. Halls, Cambridge (GB); Matthew Roberts, Cambridge (GB); Nalinkumar L. Patel, Cambridge (GB)

Correspondence Address: MARSHALL, GERSTEIN & BORUN LLP, 233 S. WACKER DRIVE, SUITE 6300, SEARS TOWER, CHICAGO, IL, 60606, US

(73) Assignee: CAMBRIDGE DISPLAY TECHNOLOGY LIMITED, Cambridgeshire (GB)

(21) Appl. No.: 10/579,050

(22) PCT Filed: Nov. 19, 2004
(86) PCT No.: PCT/GB04/04883

§ 371 Date: Mar. 13, 2007

(30) Foreign Application Priority Data
Nov. 19, 2003 (GB) 0326853.9

(51) Int. Cl. H01L 27/15; H01L 21/20

(52) U.S. Cl. 257/86; 438/22; 257/E51.018; 257/E25.032

(57) ABSTRACT

A method of forming an electroluminescent device including the steps of providing a substrate including a first electrode for injection of charge carriers of a first type, forming a semiconductor region by depositing over the substrate a composition containing a first material for transporting charge carriers of the first type and a second material for emission and transporting charge carriers of the first type, and depositing over the semiconducting region a second electrode for injection of charge carriers of a second type.

### FIELD OF THE INVENTION

The invention relates to organic electroluminescent devices and methods for the forming thereof.

### BACKGROUND OF THE INVENTION

One class of opto-electrical devices is that using an organic material for light emission or detection. The basic structure of these devices is a light emissive organic layer, for instance a film of a poly (p-phenylenevinylene) (“PPV”) or polyfluorene, sandwiched between a cathode for injecting negative charge carriers (electrons) and an anode for injecting positive charge carriers (holes) into the organic layer. The electrons and holes combine in the organic layer generating photons. In WO 90/13148 the organic light-emissive material is a polymer. In U.S. Pat. No. 4,539,507 the organic light-emissive material is of the class known as small molecule materials, such as (8-hydroxyquinoline) aluminium (“Alq3”). In a practical device one of the electrodes is transparent, to allow the photons to escape the device.

A typical organic light-emissive device (“OLED”) is fabricated on a glass or plastic substrate coated with a transparent first electrode such as indium-tin-oxide (“ITO”). A layer of a thin film of at least one electroluminescent organic material covers the first electrode. Finally, a cathode covers the layer of electroluminescent organic material. The cathode is typically a metal or alloy and may comprise a single layer, such as aluminium, or a plurality of layers such as calcium and aluminium. Other layers can be added to the device, for example to improve charge injection from the electrodes to the electroluminescent material. For example, a hole injection layer such as poly(ethylene dioxythiophene)/polystyrene sulfonate (PEDOT-PSS) or polyaniline may be provided between the anode and the electroluminescent material. When a voltage is applied between the electrodes from a power supply one of the electrodes acts as a cathode and the other as an anode

For organic semiconductors important characteristics are the binding energies, measured with respect to the vacuum level of the electronic energy levels, particularly the “highest occupied molecular orbital” (HOMO) and the “lowest unoccupied molecular orbital” (LUMO) level. These can be estimated from measurements of photoemission and particularly measurements of the electrochemical potentials for oxidation and reduction. It is well understood in this field that such energies are affected by a number of factors, such as the local environment near an interface, and the point on the curve (peak) from which the value is determined. Accordingly, the use of such values is indicative rather than quantitative.

In operation, holes are injected into the device through the anode and electrons are injected into the device through the cathode. The holes and electrons combine in the organic electroluminescent layer to form an exciton which then undergoes radiative decay to give light.

The active organic layers of an OLED are typically formed by evaporation of the materials (in the case of small molecule materials), or by solution deposition (in the case of polymeric or dendrimeric materials). Evaporation allows formation of multiple layers, in particular hole transporting and/or electron transporting layers to assist transport of charge into the electroluminescent layer. Solution-deposited materials are less amenable to formation of such multilayers because a solution-deposited layer is prone to dissolution in the solvent used to deposit a subsequent layer.

One approach that utilises charge transporting materials for solution processable systems without requiring formation of multiple layers is disclosed in WO 99148160 and WO 02/28983 wherein a hole transporting component, an electron transporting component and an emissive component are blended together.

Another approach entails incorporation of the charge transporting units described in WO 99/48160 into an electroluminescent polymer as described in WO 00/55927 which discloses a blue electroluminescent polymer of formula (a): 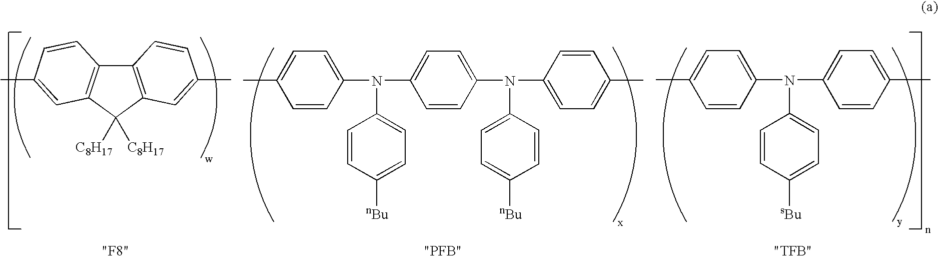
wherein w+x+y=1, w<0.5, 0≦x+y≦0.5 and n<2,

In essence, the separate hole transporting, electron transporting and emissive components disclosed in WO 99/48160 are combined into a single molecule. Conjugated chains of the F8 repeat unit provide electron transport; the TFB unit is provided for the purpose of hole transport; and the PFB repeat unit is provided as the emissive unit. The use of a single electroluminescent polymer, rather than a blend, has been found to improve lifetime of the electroluminescent materials, in particular blue electroluminescent materials whilst retaining the improved efficiency conferred by charge transporting components (by “lifetime” is meant the time for the brightness of the OLED to halve at constant current when operated under DC drive). The combination of units into a single polymer may be preferable to a blend, for example intramolecular charge transport may be preferable to intermolecular charge transport and potential difficulties caused by undesirable forms of phase separation in blends is avoided.

Co-pending application PCT GB03/01991 describes improvement in the lifetime of polymer (a) by removal of the hole transporting “TFB” repeat unit to provide a polymer wherein both hole transport and emission is provided by the “PBF” repeat unit.

The improvement in blue lifetime in replacing blends with these unblended “single component” polymers is particular significant because full colour OLEDs require red, green and blue emissive materials however, in spite of the aforementioned developments, blue emissive materials known to date still suffer from relatively short lifetime in comparison to red and green materials.

It is therefore an object of the present invention to provide an electroluminescent device, in particular an electroluminescent device comprising a blue emitter, having improved lifetime.

### SUMMARY OF THE INVENTION

The present inventors have surprisingly found that deposition of a blend comprising a hole transporting material and an electroluminescent material containing a hole transporting unit provides improved lifetime.

Accordingly, in a first aspect the invention provides a method of forming an electroluminescent device comprising the steps of:
providing a substrate comprising a first electrode for injection of charge carriers of a first type
forming a semiconducting region by depositing over the substrate a composition comprising a first material for transporting charge carriers of the first type and a second material for emission and transporting charge carriers of the first type; and
depositing over the semiconducting region a second electrode for injection of charge carriers of a second type.

By “hole transporting material” is meant a material capable of transporting holes from a hole injecting material to an electroluminescent material. Preferably, the HOMO of the hole transporting material is less than 0.7 eV, more preferably less than 0.5 eV, most preferably less than 0.2 eV, from the HOMO of the anode or hole injecting material. A typical electroluminescent device comprises an anode having a workfunction of 4.8 eV. Accordingly, the HOMO level of hole transporting materials is preferably around 4.8-5.5 eV. The HOMO level of hole transporting materials can be less than 4.8 eV in which case there is no barrier to hole injection from the anode.

The cathode of a typical device will have a workfunction of around 3 eV. Accordingly, the LUMO level of electron transporting materials is preferably around 3-3.5 eV.

The emissive segment of the second material is determined by the component of the second material having the smallest HOMO-LUMO bandgap.

Preferably, the first electrode is an anode; the second electrode is a cathode; the charge carriers of the first type are holes and the charge carriers of the second type are electrons.

The second material may comprise separate charge transporting and emissive regions or units. Alternatively, both of the functions of charge transport and emission may be provided by the same region or unit of the emissive material.

Preferably, at least one (and more preferably both) of the first material and second material are polymers, more preferably conjugated polymers.

Preferably, the first material comprises an optionally substituted repeat unit of formula (I): 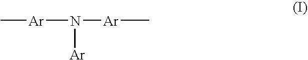
wherein each Ar is independently selected from optionally substituted aryl or heteroaryl.

Preferably, each Ar is optionally substituted phenyl. More preferably, the first repeat unit comprises an optionally substituted repeat unit of formula (II): 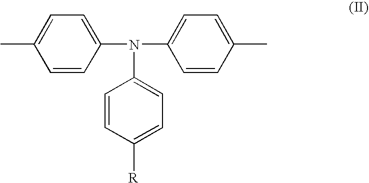
wherein each R is selected from hydrogen or a substituent. Preferred substituents R include solubilising groups, such as alkyl or alkoxy groups, and groups for modifying the electron affinity of the repeat unit, such as electron withdrawing groups.

Preferably, the repeat unit of formula (II) comprises a single nitrogen atom in its backbone.

Preferably, the second material is a polymer comprising an optionally substituted repeat unit of formula (III): 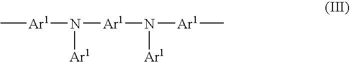
wherein each Ar¹ independently represents an optionally substituted aryl or heteroaryl.

Preferably, each Ar¹ is optionally substituted phenyl. More preferably, the first repeat unit comprises an optionally substituted repeat unit of formula (IV): 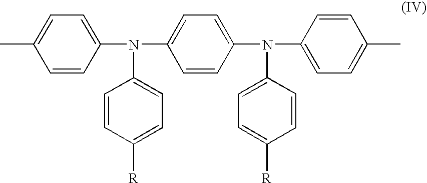
wherein R is as defined above.

Preferably, at least one (more preferably both) of the first and second materials are polymers comprising a further repeat unit selected from optionally substituted fluorene, spirofluorene, indenofluorene, phenylene or oligophenylene, preferably fluorene, more preferably 9,9-disubstituted fluorene-2,7-diyl.

Particularly preferred further repeat units are selected from optionally substituted repeat units of formula (V): 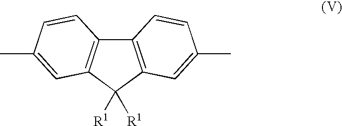
wherein each R¹ is independently selected from optionally substituted alkyl, alkoxy, aryl and heteroaryl. Particularly preferred substituents R¹ are selected from branched or linear C₁₋₁₀ alkyl and hydrocarbyl aryl.

Particularly preferred further repeat units are optionally substituted 9,9-dialkyl- or 9,9-dialkoxy-2,7-fluorenyl, most preferably 9,9-di(n-octyl)fluorene.

Preferably, the second material is capable of electroluminescence in the wavelength range 400-500 nm, most preferably 430-500 nm.

Preferably, the first material:second material ratio is in the range 5:95- 30:70, more preferably 10:90- 20:80.

Preferably, the composition is deposited from a solution in a solvent.

The solvent for the composition may be a single solvent or a blend of two or more solvents. Preferably, the solvent comprises a substituted benzene, more preferably a mono- or poly-alkylated benzene.

Preferably, peak average molecular weight of the first material is between 15 and 150 kDa, more preferably between 25 and 100 kDa, more preferably still between 30 and 80 kDa and most preferably between 40 and 60 kDa.

Preferably, the first material and the second material substantially completely phase separate. The phase separation may occur after deposition of the composition over the substrate.

In a second aspect, the invention provides an electroluminescent device obtainable by the method according to the first aspect of the invention.

### BRIEF DESCRIPTION OF THE DRAWINGS

The present invention will now be described in further detail, by way of example only, with reference to the accompanying drawings in which:

FIG. 1 shows a prior art electroluminescent device

FIG. 2 shows a comparative data of voltage required for a luminance of 100 cd/m² for a variety of electroluminescent systems.

FIG. 3 shows the effect of a change in molecular weight of the first material on lifetime of the device.

### DETAILED DESCRIPTION OF THE INVENTION

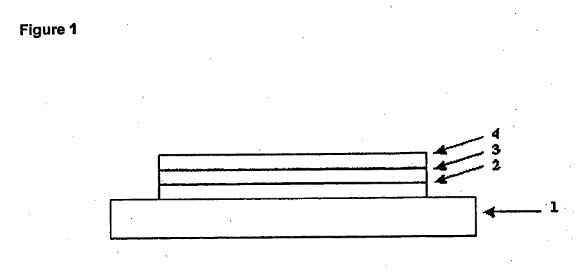

With reference to FIG. 1, the standard architecture of an optical device according to the invention, in particular an electroluminescent device, comprises a transparent glass or plastic substrate 1, an anode of indium tin oxide 2 and a cathode 4. A semiconducting region is located 3 between anode 2 and cathode 4.

Semiconducting region 3 may comprise the first and second materials according to the invention alone, or may comprise further materials. The first and second materials are preferably deposited from solution in the form of a blend, which may undergo partial or total phase separation upon evaporation of the solvent. If the first or second materials do not provide one of the functions of hole transport or electron transport, then a further material providing this function may be included in semiconducting region 3 either as a separate material blended with the first and second materials as disclosed in WO 99/48160 or as unit incorporated into the first or second material, in particular a repeat unit of a polymer as disclosed in WO 00/55927. The further material may also be provided as a separate layer within semiconducting region 3.

Where the second material is a polymer, its functions of emission and charge transport may be provided by regions comprising a single repeat unit with the polymer or by a chain of repeat units, such as a conjugated chain of polyfluorene units functioning as an electron transporting region. The different regions within such a polymer may be provided along the polymer backbone, as per U.S. Pat. No. 6,353,083, or as groups pendant from the polymer backbone as per WO 01/62869.

Where the first and second materials are polymers, they are preferably copolymers comprising an arylene or heteroarylene co-repeat unit such as a fluorene, particularly 2,7-linked 9,9 dialkyl fluorene or 2,7-linked 9,9 diaryl fluorene; a spirofluorene such as 2,7-linked 9,9-spirofluorene; an indenofluorene such as a 2,7-linked indenofluorene; or a phenyl such as alkyl or alkoxy substituted 1,4-phenylene. Each of these groups may be substituted.

Further suitable arylene or heteroarylene groups are known in this art, for example as disclosed in WO 00/55927 and WO 00/46321, the contents of which are incorporated herein by reference.

Each such polymer may be a homopolymer, copolymer, terpolymer or higher order polymer. These copolymers, terpolymers or higher order polymers include regular alternating, random and block polymers where the percentage of each monomer used to prepare the polymer may vary.

For ease of processing, it is preferred that the first and second materials are soluble. Substituents such as C₁₋₁₀ alkyl or C₁₋₁₀ alkoxy may be selected to confer solubility on the polymer in a particular solvent system. Typical solvents include mono- or poly-alkylated benzenes such as toluene and xylene or solvents such as tetrahydrofuran.

Suitable techniques for depositing solutions of the first and second materials include inkjet printing as disclosed in EP 0880303, spin-coating, dip-coating and doctor blade coating.

Two polymerisation techniques that are particularly amenable to preparation of conjugated polymers from aromatic monomers are Suzuki polymerisation as disclosed in, for example, WO 00/53656 and Yamamoto polymerisation as disclosed in, for example, “Macromolecules”, 31, 1099-1103 (1998). Suzuki polymerisation entails the coupling of halide and boron derivative functional groups; Yamamoto polymerisation entails the coupling of halide functional groups. Accordingly, it is preferred that each monomer is provided with two reactive functional groups P wherein each P is independently selected from the group consisting of (a) boron derivative functional groups selected from boronic acid groups, boronic ester groups and borane groups and (b) halide functional groups.

Although not essential, a layer of organic hole injection material (not shown) between the anode 2 and the polymer layer 3 is desirable because it assists hole injection from the anode into the layer or layers of semiconducting polymer. Examples of organic hole injection materials include poly(ethylene dioxythiophene) (PEDT/PSS) as disclosed in EP 0901176 and EP 0947123, or polyaniline as disclosed in U.S. Pat. No. 5,723,873 and U.S. Pat. No. 5,798,170.

Cathode 4 is selected from materials that have a workfunction allowing injection of electrons into the electroluminescent layer. Other factors influence the selection of the cathode such as the possibility of the adverse interactions between the cathode and the electroluminescent material. The cathode may consist of a single material such as a layer of aluminium. Alternatively, it may comprise a plurality of metals, for example a bilayer of calcium and aluminium as disclosed in WO 98/10621, elemental barium disclosed in WO 98/57381, Appl. Phys. Lett. 2002, 81(4), 634 and WO 02/84759 or a thin layer of dielectric material to assist electron injection, for example lithium fluoride disclosed in WO 00/48258 or barium fluoride, disclosed in Appl. Phys. Lett. 2001, 79(5), 2001.

Electroluminescent displays according to the invention may be monochrome displays or full colour displays (i.e. formed from red, green and blue electroluminescent materials). An electroluminescent device according to the invention may also be used for lighting, in particular as a source of white light. For example, the device may comprise a blue electroluminescent polymer with means for downconverting a portion of the blue polymer by means of red and green downconverters in order to produce white light from a blend of red, green and blue emission as disclosed in, for example, U.S. Pat. No. 6,515,314 wherein downconversion is provided by nanoparticles located within the layer of emissive material or Applied Physics Letters 80(19), 3470-3472, 2002 wherein downconverter particles are attached to the outer surface of the substrate of the device.

### EXAMPLES

### Monomer Examples

Monomers according to the invention were prepared in accordance with the scheme below:

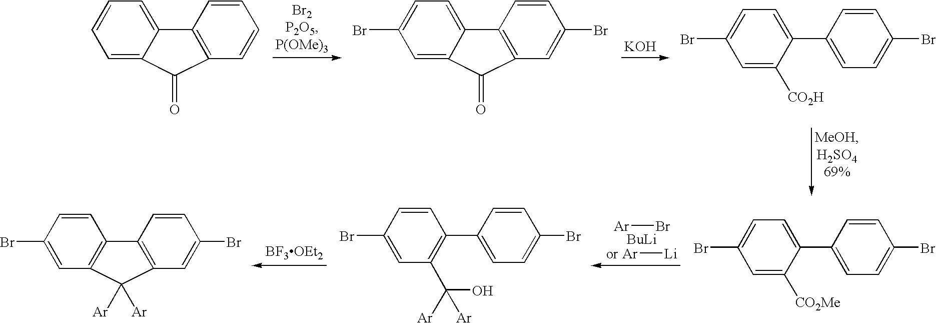

### Monomer Example M1: 2,7-dibromo-9,9-diphenylfluorene

### 2,7-Dibromofluorenone

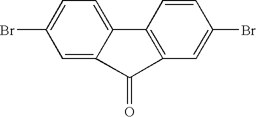

In a 3 L flange flask fluorenone (100.006 g, 0.555 mol), phosphorus pentoxide (110.148 g, 0.776 mol) and trimethylphosphate (1200 mL) were mixed. Under mechanical stirring, a solution of bromine (63 mL, 1.23 mol) in trimethylphosphate (200 mL) was quickly added. This clear solution was then heated for 22 hours at 120° C. The mixture was allowed to cool to room temperature, then poured into 3 L of water. When sodium thiosulfate was added (50.045 g) the mixture turned yellow. Stirring was maintained for 1 hour then the yellow solid was filtered. This solid was heated in methanol to remove the mono-brominated compound and gave 176.183 g (98% pure by HPLC, 94% yield).

¹ H NMR (CDCl₃) 7.73 (2H, d, J 2.0), 7.61 (2H, dd, J 7.6, 2.0), 7.36 (2H, d, J 8.0); ¹³C NMR (CDCl₃) 142.3, 137.5, 135.3, 127.9, 123.3, 121.8, 109.8.

### 4,4′-Dibromo-2-carboxylic acid-1,1′-biphenyl

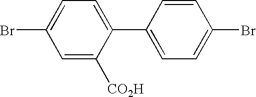

In a 2 L flange flask 2,7-dibromofluorenone (120.526 g, 0.356 mol), potassium hydroxide (finely powdered flakes, 168.327 g, 3.000 mol) and toluene (600 mL) were placed. This mixture was heated at 120° C. for four hours then left to cool to room temperature. Water was added to dissolve the solid (˜2 L) under vigorous stirring. The greenish aqueous layer was removed and the yellow toluene layer was washed twice with water. The combined aqueous layers were acidified with concentrated hydrochloric acid then the precipitated solid was filtered, dried then recrystallised from toluene to give 100.547 g of off white crystals (79% yield); ¹H NMR ((CD₃)₂CO) 8.00 (1H, d, J 2.0), 7.77 (1H, dd, J 8.0, 2.4), 7.57 (2H, d, J 8.0), 7.34 (1H, d, J 8.4), 7.29 (2H, d, J 8.8); ¹³C NMR ((CD₃)₂CO) 167.1, 140.4, 139.8, 134.2, 133.5, 132.8, 132.7, 131.2, 130.6, 121.4, 121.1.

### Methyl ester of 4,4′-dibromo-2-carboxylic acid -1,1′-biphenyl

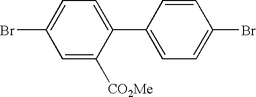

4,4-dibromo-2-carboxylic acid biphenyl (171.14 g, 0.481 mol) was suspended in methanol (700 mL) and sulfuric acid (15 mL) then heated at 80° C. for 21 hours. The solvent was removed and the oil was dissolved in ethyl acetate. This solution was washed with 2N sodium hydroxide, water, saturated sodium chloride, dried over magnesium sulfate, filtered and evaporated to give an orange oil. This oil was treated with hot methanol, on cooling the ester precipitated out and was filtered. The mother liquor was evaporated and the solid recrystallised giving additional product. The ester was 100% pure by GCMS, a yield of 123.27 g (69%) was obtained; ¹HNMR (CDCl₃) 7.99 (1H, d, J 2.0), 7.64 (1H, dd, J 8.0, 1.6), 7.51 (2H, d, J 8.4), 7.19 (1H, d, J 8.8), 7.13 (2H, d, J 8.8), 3.67 (3H, s) ; ¹³C NMR (CDCl₃) 167.1, 140.3, 139.1, 134.4, 132.9, 132.1, 132.0, 131.3, 129.8, 121.9, 121.5, 52.3; GCMS: M⁺=370

### 4,4′-dibromo-2-diphenyl alcohol -1,1′-biphenyl

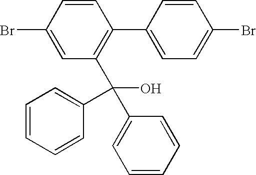

4,4-dibromo-2-methyl ester-biphenyl (24.114 g, 65.1 mmol) was dissolved in dry diethyl ether (120 mL) and the solution was cooled to −60° C. by using an isopropanol/dry ice bath. Phenyl lithium (1.8 M solution in cyclohexane-ether, 91 mL) was then added dropwise. The mixture was stirred and let to warm to room temperature. The reaction was complete after four hours. Water was added (70 mL) then the aqueous layer washed once with diethyl ether. Combined organic phases were washed with sodium chloride, dried over magnesium sulfate, filtered and evaporated to give a yellow powder. Recrystallisation from isopropanol afforded 19 g of white solid (59% yield);GC-MS (m/z, relative intensity %) 494 (M⁺, 100); ¹HNMR (CDCl₃) 7.43 (1H, dd, J 8.4, 2.4), 7.28 (6H, m), 7.23 (2H, d, J 8.0), 7.11 (4H, m), 6.99 (1H, d, J 2.4), 6.94 (1H, d, J 8.4), 6.61 (2H, d, J 8.4); ¹³C NMR (CDCl₃) 147.5, 146.7, 140.3, 139.3, 134.0, 133.0, 131.2, 131.1, 130.3, 128.2, 128.1, 127.8, 121.8, 121.3, 83.2.

### 2,7-dibromo-9,9-diphenylfluorene

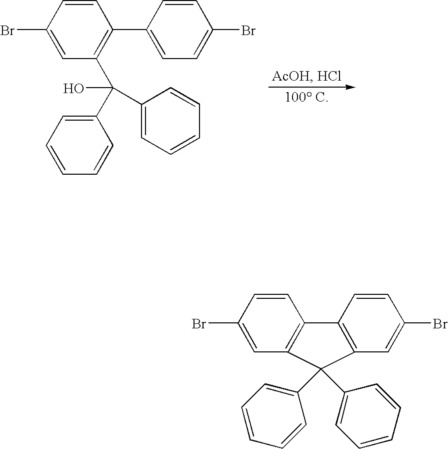

The alcohol (69.169 g, 140 mmol) and glacial acetic acid (450 ml) were stirred and heated to reflux, then concentrated hydrochloric acid (0.5 ml) was added dropwise. When the addition was completed the mixture was heated for one hour and then cooled. The reaction mixture was poured into water (500 ml), after which the solid was filtered off. The white solid was recrystallised from n-butyl acetate three times to give 20.03 g of desired product (99.59% by HPLC, 30% yield). ¹H NMR (CDCl₃), δ/ppm: 7.58 (2H, d, J 7.6), 7.49 (2H, d, 1.2), 7.48 (2H, dd, 1.6 ), 7.25 (6H, m), 7.14 (4H, m).

¹³C NMR (CDCl₃), δ/ppm: 153.2, 144.6, 138.3, 131.1, 129.6, 128.7, 128.2, 127.4, 122.0, 121.7, 65.8.

### Monomer Examples M2-M4

Monomers with Ar groups as detailed in the table below were prepared in accordance with the scheme and general experimental process outlined above. Aryllithium compounds corresponding to Ar groups shown in the table were prepared from the corresponding aryl bromide.

| Monomer | | Yield of |
|---|---|---|
| example no. | Ar | monomer |
| M2 | 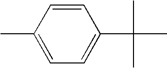 | 90% |
| M3 | 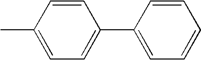 | 24% |
| M4 | 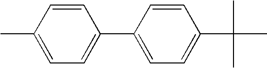 | 22% |

### Polymer Example P1

A blue electroluminescent polymer according to the invention was prepared in accordance with the process of WO 00/53656 by reaction of 9,9-di-n-octylfluorene-2,7-di(ethylenylboronate) (0.65 equivalents), 2,7-dibromo-9,9-diphenylfluorene (0.30 equivalents) and N,N′-di(4-bromophenyl)-N,N′-di(4-n-butylphenyl)-1,4-diaminobenzene (0.05 equivalents) to give polymer P1:

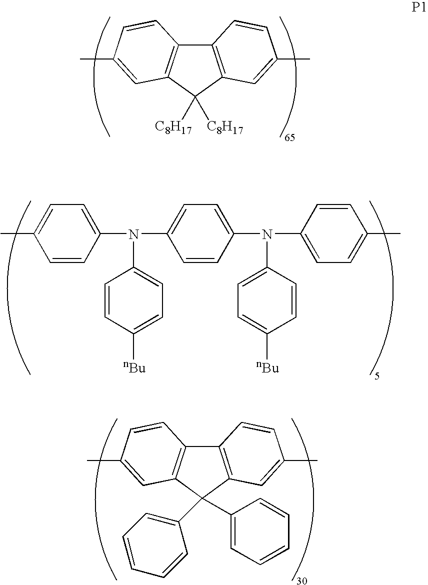

### Device Example

General Procedure

Onto indium tin oxide supported on a glass substrate (available from Applied Films, Colorado, USA) was deposited a layer of PEDT/PSS, available from Bayer™ as Baytron P™ by spin coating. A solution of a blend of TFB and polymer P1 were deposited over the PEDT/PSS layer by spin-coating. Onto the polymer P1 was deposited by evaporation a cathode consisting of a first layer of barium and a second, capping layer of aluminium.

Lifetime

Devices according to the invention were made according to the general procedure using a range of P1:TFB ratios and different solvents. For the purposes of comparison, a device comprising no TFB was made. In each case, at least two devices were made. Devices were driven at 800 cd/m².

| P1:F8-TFB ratio | Deposition solvent | Lifetime (hours) |
|---|---|---|
| 80:20 | ortho-xylene | 74, 77, 78 |
| 95:5 | ortho-xylene | 69, 91, 79 |
| 80:20 | anisole:cyclohexylbenzene | 107, 95 |
| | 50:50 | |
| 100:0 | o-xylene | 21, 16 |

As can be seen from the results, lifetime of devices comprising a blend according to the invention show around a four- to five-fold increase in lifetime. The effect of using a different solvent on lifetime indicates that phase separation effects in the blend play a role in determining device performance. The improvement in lifetime of P1 by blending with F8-TFB copolymer is surprising given that removal of TFB units from polymer (a) described above was previously found to improve lifetime, and given than unblended polymers have previously been found to afford superior lifetimes as compared to blended polymers. Without wishing to be bound by any theory, it is believed that the blend according to the invention undergoes vertical phase separation such that F8-TFB copolymer migrates towards the anode side of the device which would, in effect, result in formation of a hole transporting layer of F8-TFB located between the anode and the electroluminescent layer which would also act to serve as a barrier against ingress of impurities from ITO and/or PEDOT into the electroluminescent material. Deposition of a hole transporting layer followed by an electroluminescent layer is well known in the art, however the present invention enables formation of a hole transporting layer and an electroluminescent layer in a one-step process. Furthermore, the present invention takes advantage of phase-separation effects in order to, in effect, form a multilayer device thus overcoming the aforementioned difficulty in forming multilayers of solution processable materials.

Drive Voltage

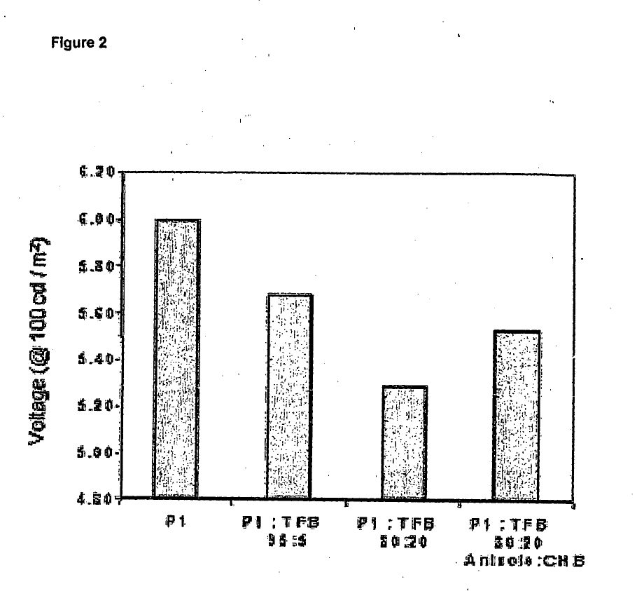

As can be seen from FIG. 2, a reduction in drive voltage is achieved for the blended systems according to the invention as compared to the control. A reduction is obtained across a range of different TFB:Polymer 1 ratios and for different solvents.

Quantum Efficiency

| | | Maximum | Quantum |
|---|---|---|---|
| | | quantum | efficiency @ 100 |
| Example | Solvent | efficiency (%) | cd/m² (%) |
| Comparative | ortho-xylene | 0.6 | 0.4 |
| polymer C1 | | | |
| (see below) | | | |
| P1:TFB 100:0 | ortho-xylene | 2.3 | 2.2 |
| P1:TFB 80:20 | ortho-xylene | 3.0 | 2.3 |
| P1:TFB 80:20 | anisole:cyclo- | 3.2 | 2.5 |
| | hexylbenzene | | |
| | 50:50 | | |

As can be seen, there is a significant increase in maximum quantum efficiency for blended systems according to the invention as compared to polymer P1 alone, as well as a marginal increase in quantum efficiency at 100 cd/m².

TFB Within an Electroluminescent Polymer vs TFB as a Separate Material in a Blend

The effect of removing the “TFB” repeat unit from the comparative polymer C1 (structure shown below) to give polymer P1, and providing the “TFB” component as a separate material in a blend rather than as a component of the same polymer is surprising.

Comparison of devices containing polymers C1 and P1 alone show that removal of “TFB” repeat units from polymer C1 results in a significant improvement in performance. In view of this, it is surprising that the inclusion of “TFB” in the form of the hole transporting material F8-TFB in a blend improves device performance, and indicates the advantageous effect of phase separation. 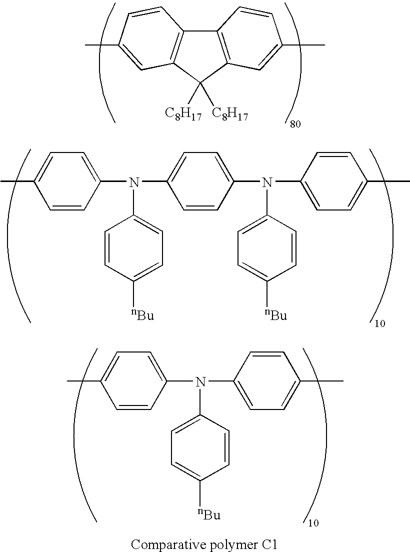
Spin Coating vs Ink Jet Printing

As shown above, blending additional hole transporting material into a layer comprising an electroluminescent material which has hole transporting functionality has been found to have advantageous effects on the resultant device such as increased lifetime, reduced drive voltage and increased quantum efficiency.

These advantageous effects have been observed for both spun coated devices (as illustrated above) and printed devices. For example, the table shown below indicates that blending of a hole transporter increases the lifetime of the device for both spin coated layers and ink jet printed layers. The devices were driven at 1600 cd/m².

| P1:F8-TFB ratio | Method of deposition | Average Lifetime (hours) |
|---|---|---|
| 100:0 | Printed | 2 |
| 80:20 | Printed | 33 |
| 80:20 | Spin coated | 27 |

As can be seen from the results, lifetime of devices comprising a blend are increased for both spin coated and ink jet printed layers. The lifetime for ink jet printed devices is slightly higher than from spin coated layers.

The table shown below indicates that pulsed lifetimes follow a similar trend to the DC results in that a large increase in lifetime is observed for both spin coated and ink jet printed devices. The devices were pulsed at 14000 cd/m².

| P1:F8-TFB ratio | Method of deposition | Average Lifetime (hours) |
|---|---|---|
| 100:0 | Printed | 21 |
| 80:20 | Printed | 121 |
| 80:20 | Spin coated | 126 |

As can be seen in the table below, there is a significant increase in maximum quantum efficiency for blended systems according to the invention as compared to polymer P1 alone, as well as a marginal increase in quantum efficiency at 100 cd /m².

| | | Maximum | Quantum |
|---|---|---|---|
| | Method of | quantum | efficiency @ 100 |
| Example | deposition | efficiency (%) | cd/m² (%) |
| P1:TFB 100:0 | Printed | 1.9 | 1.78 |
| P1:TFB 80:20 | Printed | 2.4 | 1.84 |
| P1:TFB 80:20 | Spin coated | 2.8 | 2.0 |

Dependence on Molecular Weight of Hole Transporter in the Blend

The large improvement in performance by adding hole transporting material to the electroluminescent material in a blend (rather than combining the hole transporter wholly within an electroluminescent polymer) suggests that the hole transporting material is vertically phase separating. As the hole transporter preferentially moves to the anode, the final structure is similar to that obtained when the hole transporter and electroluminescent layers are spun/printed separately. This process of phase separation is dependent on various parameters of the process and the properties of the materials such as molecular weight.

A range of TFB polymers have been prepared with varying molecular weight. Blending TFB as before results in an increase in the conductivity. It has been found that this increase in conductivity is sensitive to the molecular weight of the TFB.

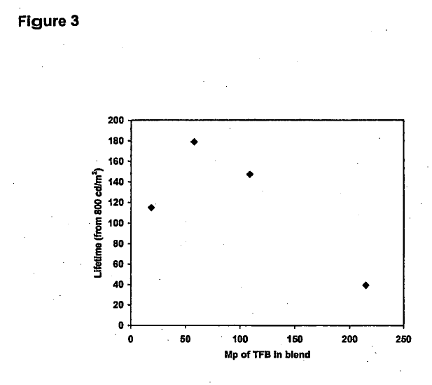

The effect of varying the molecular weight of TFB on lifetime is shown in the table below and FIG. 3. The devices were driven at 800 cd/m².

| P1:F8-TFB ratio | Mp of TFB (kDa) | Average Lifetime (hours) |
|---|---|---|
| 100:0 | N/A | 15 |
| 80:20 | 19 | 100 |
| 80:20 | 58 | 179 |
| 80:20 | 109 | 147 |
| 80:20 | 215 | 39 |

The optimum lifetime occurs around a peak average molecular weight Mp˜50 kDa. There is a large drop in the lifetime when high molecular weight TFB is used in the blend.

The molecular weight of the TFB is critical to the performance of the blend system. TFB with Mp˜50 k gives optimum performance for the blends, with performance reduced for lower and higher molecular weight TFBs.

By washing away the upper portion of the blended layer, the composition of the few nanometres close to the anode can be probed spectroscopically. This technique has confirmed that vertical phase separation occurs in the blends with the hole transporter (e.g. TFB) preferentially moving to the anode. The molecular weight of the hole transporter is critical for this process, with high molecular weight samples showing no sign of hole transporter migration to the anode.

Although the present invention has been described in terms of specific exemplary embodiments, it will be appreciated that various modifications, alterations and/or combinations of features disclosed herein will be apparent to those skilled in the art without departing from the spirit and scope of the invention as set forth in the following claims.

1. A method of forming an electroluminescent device comprising the steps of:
providing a substrate comprising a first electrode for injection of charge carriers of a first type;
forming a semiconducting region by depositing over the substrate a composition comprising a first material for transporting charge carriers of the first type and a second material for emission and transporting charge carriers of the first type; and
depositing over the semiconducting region a second electrode for injection of charge carriers of a second type.

2. A method according to claim 1 wherein the first electrode is an anode; the second electrode is a cathode; the charge carriers of the first type are holes and the charge carriers of the second type are electrons.

3. A method according to claim 1 wherein at least one of the first material and second material is a polymer.

4. A method according to claim 3 wherein the first material comprises an optionally substituted repeat unit of formula (I): 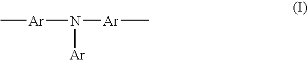
wherein each Ar is independently selected from optionally substituted aryl or heteroaryl.

5. A method according to claim 4 wherein each Ar is optionally substituted phenyl.

6. A method according to claim 5 wherein the optionally substituted repeat unit of formula (I) is an optionally substituted repeat unit of formula (II): 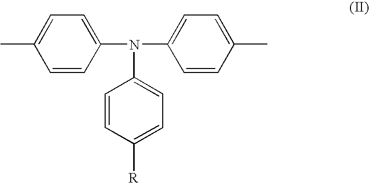
wherein each R is selected from hydrogen or a substituent.

7. A method according to claim 6 wherein the repeat unit of formula (II) includes a single nitrogen atom in its backbone.

8. A method according to claim 4 wherein the second material is a polymer comprising an optionally substituted repeat unit of formula (III): 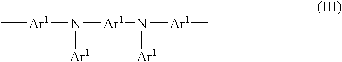
wherein each Ar¹ independently represents an optionally substituted aryl or heteroaryl.

9. A method according to claim 8 wherein each Ar¹ is optionally substituted phenyl.

10. A method according to claim 9 wherein the optionally substituted repeat unit of formula (III) is an optionally substituted repeat unit of formula (IV): 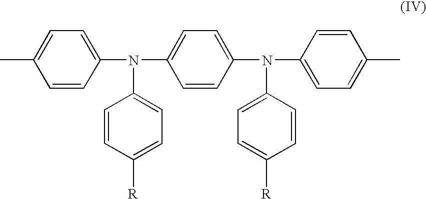
wherein R is as defined in claim 6.

11. A method according to claim 1, wherein at least one of the first and second materials is an electron transporter.

12. A method according to claim 1, wherein at least one of the first and second materials is a polymer comprising a repeat unit selected from optionally substituted fluorene, spirofluorene, indenofluorene, phenylene and oligophenylene.

13. A method according to claim 12 wherein the repeat unit is selected from optionally substituted repeat units of formula (V): 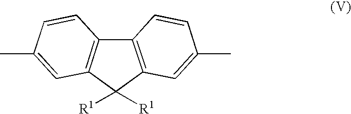
wherein each R¹ is independently selected from optionally substituted alkyl, alkoxy, aryl and heteroaryl, and the two groups R¹ may be linked.

14. A method according to claim 1 wherein the second material is capable of electroluminescence in the wavelength range 400 nm-500 nm.

15. A method according to claim 1 wherein the first material:second material ratio is in the range 5:95 to 30:70.

16. A method according to claim 1 comprising depositing the composition from a solution in a solvent.

17. A method according to claim 16 wherein the solvent comprises a substituted benzene.

18. A method according to claim 17 wherein the solvent comprises a mono- or poly-alkylated benzene.

19. A method according to claim 1 wherein peak average molecular weight of the first material is between 15 kDa and 150 kDa.

20. A method according to claim 1 wherein the first material and the second material substantially completely phase separate.

21. An electroluminescent device obtained according to the method of claim 1.

22. A method according to claim 3 wherein said polymer is a conjugated polymer.

23. A method according to claim 12 wherein said repeat unit is fluorine.

24. A method according to claim 23 wherein said repeat unit is 9,9-disubstituted fluorine-2,7-diyl

25. A method according to claim 14 wherein said wavelength range is 430 mm to 500 mm.

26. A method according to claim 15 wherein said range is 10:90-20:80.

27. A method according to claim 19 wherein said peak average molecular weight is between 25 kDa and 100 kDa.

28. A method according to claim 19 wherein said peak average molecular weight is between 30 kDa and 80 kDa.

29. A method according to claim 19 wherein said peak average molecular weight is between 40 kDa and 60 kDa.
